(19) United States
(12) Patent Application Publication
(10) Pub. No.: US 2015/0223341 A1
(43) Pub. Date: Aug. 6, 2015

(54) EMBEDDED BOARD, PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Sang Hoon KIM, Suwon (KR); Tae Hong MIN, Suwon (KR); Young Gwan KO, Suwon (KR); Hye Jin KIM, Suwon (KR); Suk Hyeon CHO, Suwon (KR); Chil Woo KWON, Suwon (KR); Jung Han LEE, Suwon (KR)

(73) Assignee: SAMSUNG ELECTRO-MECHANICS CO., LTD., Suwon (KR)

(21) Appl. No.: 14/597,795

(22) Filed: Jan. 15, 2015

(30) Foreign Application Priority Data
Feb. 6, 2014 (KR) 10-2014-0013793

(51) Int. Cl. H05K 1/18; H05K 3/30; H05K 3/00; H05K 3/02; H05K 1/11; H05K 1/02

(52) U.S. Cl. CPC H05K 1/183; H05K 1/115; H05K 1/0284; H05K 3/007; H05K 3/022; H05K 3/30

(57) ABSTRACT

An embedded board, a printed circuit board, and a method of manufacturing the same. According to one embodiment of the present invention, an embedded board includes: a core insulating layer formed with a first cavity; a first circuit layer formed on one surface of the core insulating layer; a build-up insulating layer formed on one surface of the core insulating layer and formed with a second cavity extending from the first cavity; devices disposed in the first cavity and the second cavity and formed to protrude from one surface of the core insulating layer; a first insulating layer formed on the other surface of the core insulating layer and filling the first cavity and the second cavity; and a build-up circuit layer and a via formed in the build-up insulating layer.

### CROSS REFERENCE TO RELATED APPLICATION

This application claims the foreign priority benefit of Korean Patent Application No. 10-2014-0013793, filed on Feb. 6, 2014, entitled “Embedded Board, Printed Circuit Board, And Method Of Manufacturing The Same” which is hereby incorporated by reference in its entirety into this application.

### BACKGROUND

1. Technical Field

Embodiments of the present invention relate to an embedded board, a printed circuit board, and a method of manufacturing the same.

2. Description of Related Art

With the increasing demand for multi-functional, small and thin cellular phones and electronic devices of information technology (IT), a technology of embedding electronic components, such as ICs, semiconductor chips, active devices and passive devices, into a substrate to meet technological demands has been required. Recently, technologies of embedding components into the substrate by various methods have been developed.

According to the general component embedded board, an insulating layer of the substrate is formed with a cavity. Then, electronic components, such as various devices, ICs, and semiconductor chips, are embedded into the cavity. Next, an adhesive resin, such as prepreg, is applied into the cavity and on an insulating layer into which the electronic components are embedded. As described above, the electronic components are fixed and the insulating layer is formed, by applying the adhesive resin (See U.S. Pat. No. 7,886,433).

### SUMMARY

Embodiments of the present invention have been made in an effort to provide an embedded board, a printed circuit board, and a method of manufacturing the same capable of having a buffering effect against an external impact.

Further, the embodiments have been made in an effort to provide an embedded board, a printed circuit board, and a method of manufacturing the same capable of improving reliability of a signal transfer by overcoming a plating defect of a via.

According to an embodiment of the present invention, there is provided an embedded board including: a core insulating layer formed with a first cavity; a first circuit layer formed on one surface of the core insulating layer; a build-up insulating layer formed on one surface of the core insulating layer and formed with a second cavity extending from the first cavity; devices disposed in the first cavity and the second cavity and formed to protrude from one surface of the core insulating layer; a first insulating layer formed on the other surface of the core insulating layer and filling the first cavity and the second cavity; and a via formed in the build-up insulating layer.

The first insulating layer and the build-up insulating layer may be made of different materials.

The first insulating layer may be made of a solder resist.

The embedded board may further include: a second circuit layer formed on the other surface of the core insulating layer.

The second circuit layer may include a first external connection pad and the first insulating layer may be formed with an opening through which the first external connection pad is exposed.

The embedded board may further include: a build-up circuit layer formed on the build-up insulating layer.

The via may include a first via which electrically connects the build-up circuit layer to the device and a second via which electrically connects the first circuit layer to the build-up circuit layer.

The first via and the second via may have the same height.

The embedded board may further include: a second insulating layer formed on the build-up circuit layer.

The build-up circuit layer may include a second external connection pad and the second insulating layer may be formed with an opening through which the second external connection pad is exposed.

The build-up insulating layer and the build-up circuit layer may be each formed in multi layers.

According to another embodiment of the present invention, there is provided a method of manufacturing an embedded board, including: preparing a core insulating layer which is formed with a through type first cavity and is formed with a first circuit layer including a second cavity extending from the first cavity; attaching the core insulating layer so as to contact the first circuit layer to one surface or both surfaces of the first carrier member; disposing the device in the first cavity and the second cavity; forming a first insulating layer which is formed on the other surface of the core insulating layer and is formed to fill the first cavity and the second cavity; removing the first carrier member; and forming a build-up insulating layer on one surface of the core insulating layer.

In the preparing of the core insulating layer, a second circuit layer may be further formed on the other surface of the core insulating layer.

The second circuit layer may include a first external connection pad and in the forming of the first insulating layer, the first insulating layer may be formed with an opening through the first external connection pad is exposed.

The method of manufacturing an embedded board may further include: after the forming of the build-up insulating layer, forming a build-up circuit layer and a via on the build-up insulating layer.

The method of manufacturing an embedded board may further include: after the forming of the build-up circuit layer and the via, forming a second insulating layer on the build-up circuit layer.

The build-up circuit layer may include a second external connection pad and in the forming of the second insulating layer, the second insulating layer may be formed with an opening through the second external connection pad is exposed.

The first insulating layer and the build-up insulating layer may be made of different materials.

The first insulating layer may be made of a solder resist.

In the forming of the build-up circuit layer and the via, a first via which electrically connects the build-up circuit layer to the device and a second via which electrically connects the first circuit layer to the build-up circuit layer may be formed.

The first via and the second via may have the same height.

The build-up insulating layer and the build-up circuit layer may be each formed in multi layers.

The method of manufacturing an embedded board may further include: after the removing of the first carrier member, attaching a core insulating layer on which the device is disposed so as to contact the first insulating layer to one surface or both surfaces of the second carrier member.

The method of manufacturing an embedded board may further include: after the forming of the build-up insulating layer, removing the second carrier member.

According to still another embodiment of the present invention, there is provided a printed circuit board, including: a core insulating layer formed with a cavity; a build-up layer formed on one surface of the core insulating layer; a solder resist formed on the other surface of the core insulating layer; and a device disposed in the cavity, wherein at least a portion of the cavity is filled with a solder resist.

The solder resist filled in the cavity may be formed around the device.

The solder resist filled in the cavity and the solder resist formed on the other surface of the core insulating layer may be continuously formed.

A sum of a thickness of the solder resist filled in the cavity and a thickness of the solder resist formed on the other surface of the core insulating layer may be larger than that of the core insulating layer.

The solder resist filled in the cavity may be formed to protrude from one surface of the core insulating layer.

According to still yet another embodiment of the present invention, there is provided a method of manufacturing a printed circuit board, including: preparing a core insulating layer formed with a cavity; attaching a carrier member to one surface of the core insulating layer; disposing a device in the cavity; forming a solder resist on the other surface of the core insulating layer and in the cavity; removing the carrier member; and forming a build-up insulating layer on one surface of the core insulating layer.

The method of manufacturing a printed circuit board may further include: after the forming of the build-up insulating layer, forming a build-up circuit layer and a via on the build-up insulating layer.

The method of manufacturing a printed circuit board may further include: after the forming of the build-up circuit layer and the via, forming a solder resist layer on one surface of the build-up circuit layer.

According to another embodiment, a printed circuit board includes: a core insulating layer formed with a cavity; a build-up layer formed on a first surface of the core insulating layer and having a recess on a side of the build-up layer facing the first surface of core insulating layer; a device, partly located in the cavity, protruding out of the cavity and into the recess. The printed circuit board may be formed by a method including: arranging the device and the core insulating layer formed with the cavity on a carrier, such that the device is inside the cavity with a bottom base on the carrier and the first surface of the core insulating layer is elevated to a position above the bottom base of the device; forming a further insulating layer by filling a space around the device, such that the further insulating layer is partially in the cavity and protruding out of the cavity; and removing the carrier and then forming the build-up layer on the first surface of the core insulating layer

Additional aspects and/or advantages will be set forth in part in the description which follows and, in part, will be apparent from the description, or may be learned by practice of the invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified view illustrating an embedded board according to an embodiment of the present invention;

FIGS. 2 through 10 are exemplified views illustrating a method of manufacturing an embedded board according to the embodiment of the present invention;

FIG. 11 is an exemplified view illustrating a printed circuit board according to an embodiment of the present invention; and

FIGS. 12 through 18 are exemplified views illustrating a method of manufacturing a printed circuit board according to the embodiment of the present invention.

### DESCRIPTION OF EMBODIMENTS

Features and advantages of the present invention will be more clearly understood from the following detailed description of the embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, a touch sensor according to embodiments of the present invention will be described in detail with reference to the attached drawings.

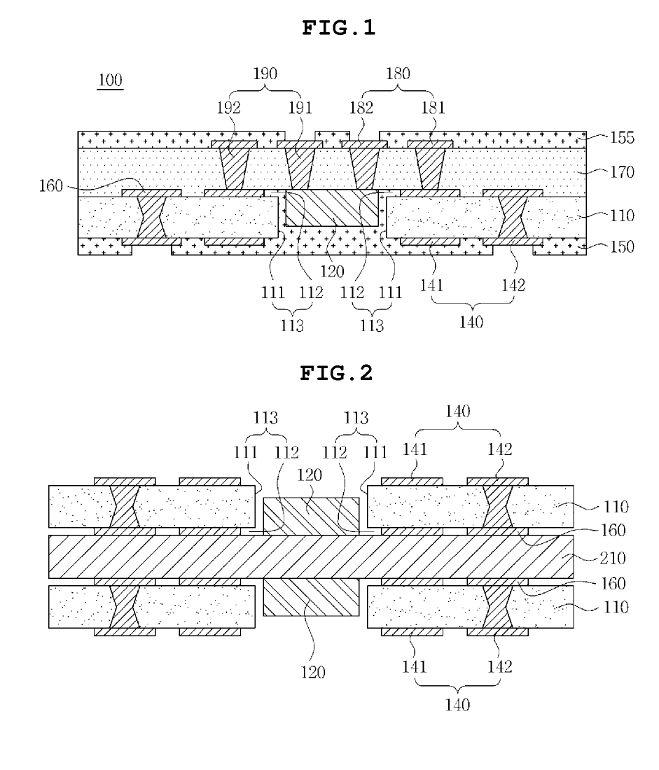

FIG. 1 is an exemplified view illustrating an embedded board according to an embodiment of the present invention.

Referring to FIG. 1, an embedded board 100 according to an embodiment of the present invention may include a core insulating layer 110, a first circuit layer 160, a second circuit layer 140, a first insulating layer 150, a second insulating layer 155, a build-up insulating layer 170, a build-up circuit layer 180, a via 190, and a device 120.

The core insulating layer 110 may be generally made of a composite polymer resin used as an interlayer insulating material. For example, the core insulating layer 110 may be made of prepreg or an ajinomoto build-up film (ABF). In addition, the core insulating layer 110 may use an epoxy based resin, such as FR-4 and bismaleimide triazine (BT), but is not particularly limited thereto. Further, the core insulating layer 110 may be formed using the copper clad laminate (CCL). The embodiment of the present invention illustrates that the core insulating layer 110 is configured of a single insulating layer, but is not limited thereto. That is, an inside of the core insulating layer 110 may be formed with an insulating layer and a circuit layer which are configured of at least one layer.

According to the embodiment of the present invention, the core insulating layer 110 may include a first cavity 111. The first cavity 111 may be formed to penetrate through the core insulating layer 110.

The first circuit 160 may be formed on one surface of the core insulating layer 110. The first circuit layer 160 may be made of a conductive material. For example, the first circuit layer 160 may be made of copper (Cu). However, a material forming the first circuit layer 160 is not limited to copper. That is, any material which is used as a conductive material for a circuit in a circuit board field may be applied to the first circuit layer 160 without being limited.

The second circuit layer 140 may be formed on the other surface of the core insulating layer 110. The second circuit layer 140 may be made of a conductive material. For example, the second circuit layer 140 may be made of copper (Cu). However, a material forming the second circuit layer 140 is not limited to copper. That is, any material which is used as a conductive material for a circuit in a circuit board field may be applied to the second circuit layer 140 without being limited. The second circuit layer 140 may include a second circuit pattern 141 and a first external connection pad 142. The first external connection pad 142 may be electrically connected to the outside. The first external connection pad 142 may be formed with the external connection terminal (not illustrated) such as a solder ball and a solder bump.

The build-up insulating layer 170 may be formed on one surface of the core insulating layer 110. That is, the build-up insulating layer 170 may be formed on one surface of the core insulating layer 110 and thus may be formed to embed the first circuit layer 160. The build-up insulating layer 170 may be generally made of the composite polymer resin used as the interlayer insulating material. For example, the build-up insulating layer 170 may be made of an epoxy based resin, such as prepreg, ajinomoto build-up film (ABF), FR-4, and bismaleimide triazine (BT). However, according to the embodiment of the present invention, a material forming the build-up insulating layer 170 is not limited thereto. The build-up insulating layer 170 according to the embodiment of the present invention may be selected from insulating materials known in the circuit board field. FIG. 1 illustrates that the build-up insulating layer 170 is formed in one layer, but is not limited thereto. The build-up insulating layer 170 may be formed in one layer as well as multiple layers.

According to the embodiment of the present invention, the build-up insulating layer 170 may include a second cavity 112. The second cavity 112 may be formed to extend from the first cavity 111 of the core insulating layer 110. Here, the second cavity 112 may be formed so as not to penetrate through the build-up insulating layer 170. The illustrated second cavity 112 may also be described as a recess formed into the build-up insulating layer.

The device 120 may be embedded in the core insulating layer 110 and the build-up insulating layer 170. That is, the device 120 may be disposed in a cavity 113. Here, the cavity 113 may include the first cavity 111 and the second cavity 112. The device 120 is disposed in the cavity 113 and thus one of the device 120 may be formed to more protrude than one surface of the core insulating layer 110 as illustrated in FIG. 1. For example, one surface of the device 120 may be formed to be disposed on the same line as one surface of the first circuit layer 160. The device 120 according to the embodiment of the present invention may be any of the active device and the passive device.

The build-up circuit layer 180 may be formed on the build-up insulating layer 170. The build-up circuit layer 180 may be made of a conductive material. For example, the build-up circuit layer 180 may be made of copper (Cu). However, a material forming the build-up circuit layer 180 is not limited to copper. That is, any material which is used as a conductive material for a circuit in a circuit board field may be applied to the build-up circuit layer 180 without being limited. FIG. 1 illustrates that the build-up circuit layer 180 is configured of one layer, but is not limited thereto. The build-up circuit layer 180 may be formed in one layer as well as multi layers. The build-up circuit layer 180 formed at the outermost layer may include a build-up circuit pattern 181 and a second external connection pad 182. The second external connection pad 182 may be electrically connected to the outside. The second external connection pad 182 may be formed with the external connection terminal (not illustrated) such as a solder ball and a solder bump.

The via 190 may be formed inside the build-up insulating layer 170. The via 190 may include a first via 191 and a second via 192. For example, the first via 191 may electrically connect the build-up circuit 180 to the device 120. The second via 192 may electrically connect the build-up circuit layer 180 to the first circuit layer 160. According to the embodiment of the present invention, since the device 120 is formed to protrude from the core insulating layer 110, the first via 191 and the second via 192 may be formed to have a similar height. That is, a height difference between the first via 191 and the second via 192 may be equal to or less than a height difference between one surface of the first circuit layer 160 and one surface of the second cavity 112. For example, when the one surface of the first circuit layer 160 and the one surface of the device 120 are disposed on the same line, the first via 191 and the second via 192 may be formed to have the same height. As the height of the first via 191 is equal or similar to that of the second via 192, the plating defect which occurs due to the difference in a size at the time of forming the via may be prevented. Here, when the via having different sizes is formed, the plating defect may include the case in which any one of the vias is excessively plated or the case in which the via hole is not completely filled. As such, the plating defect may be prevented and thus the reliability of the signal transfer may be improved. FIG. 1 illustrates that the via 190 is formed only on one layer, but is not limited thereto. For example, when the build-up insulating layer 170 and the build-up circuit layer 180 are formed in multi layers, the via 190 may be formed to electrically connect the build-up circuit layers 180 of each layer with each other if necessary.

The first insulating layer 150 may be formed on the other surface of the core insulating layer 110. The first insulating layer 150 may be formed to embed the second circuit layer 140 which is formed on the other surface of the core insulating layer 110. For example, when the second circuit layer 140 includes the first external connection pad 142, the first insulating layer 150 may be patterned to expose the first external connection pad 142. Further, the first insulating layer 150 may be formed to fill the cavity 113. Therefore, one surface of the first insulating layer 150 filled in the cavity 113 and one surface of the device 120 may be disposed on the same line.

The first insulating layer 150 may be made of an insulating layer which is generally used as an interlayer insulating material. That is, the first insulating layer 150 according to the embodiment of the present invention may be selected from insulating materials known in the circuit board field. However, according to the embodiment of the present invention, the first insulating layer 150 may be made of a material different from that of the build-up insulating layer 170. For example, the first insulating layer 150 may be made of a solder resist. The solder resist having a lower modulus than that of the core insulating layer 110 has an effect of buffering the external impact. Therefore, the embedded board 100 and the device 120 may be protected from the impact due to the bonding process or other process by filling the cavity 113 with the first insulating layer 150 which is made of the solder resist. However, the first insulating layer 150 is not limited to the solder resist, the first insulating layer 150 may be selectively made from the insulating materials having the lower modulus than that of the core insulating layer 110.

The second insulating layer 155 is formed on the build-up insulating layer 170 and thus may be formed to embed the build-up circuit layer 180. For example, when the build-up circuit layer 180 includes the second external connection pad 182, the second insulating layer 155 may be patterned to expose the second external connection pad 182.

The second insulating layer 155 may be made of an insulating layer which is generally used as an interlayer insulating material. For example, the second insulating layer 155 may be made of the solder resist. However, the material of the second insulating layer 155 is not limited to the solder resist. That is, the second insulating layer 155 according to the embodiment of the present invention may be selected from the insulating materials known in the circuit board field.

The embodiment of the present invention illustrates the second circuit layer 140 and the first insulating layer 150 as the outermost layer, but is not limited thereto. Although not illustrated, the build-up layer may be further formed on the second circuit layer 140 and the first insulating layer 150 by the selection of those skilled in the art.

FIGS. 2 through 10 are exemplified views illustrating a method of manufacturing an embedded board according to an embodiment of the present invention.

Referring to FIG. 2, the core insulating layer 110 and the device 120 may be attached to a first carrier member 210.

The first carrier member 210 may serve to support the core insulating layer 110 and the device 120 so as to dispose the device 120 in the cavity 113. The first carrier member 210 may be selectively made from the known materials used to form the embedded board.

The core insulating layer 110 may be generally made of a composite polymer resin used as an interlayer insulating material. For example, the core insulating layer 110 may be made of prepreg or an ajinomoto build-up film (ABF). In addition, the core insulating layer 110 may use an epoxy based resin, such as FR-4 and bismaleimide triazine (BT), but is not particularly limited thereto. Further, the core insulating layer 110 may be formed using the copper clad laminate (CCL). The embodiment of the present invention illustrates that the core insulating layer 110 is configured of a single insulating layer, but is not limited thereto. That is, an inside of the core insulating layer 110 may be formed with an insulating layer and a circuit layer which are configured of at least one layer.

According to the embodiment of the present invention, the core insulating layer 110 may include a first cavity 111. The first cavity 111 may be formed to penetrate through the core insulating layer 110.

According to the embodiment of the present invention, the first circuit layer 160 may be formed on one surface of the core insulating layer 110. According to the embodiment of the present invention, the second cavity 112 extending from the first cavity 111 of the core insulating layer 110 may be formed on the first circuit layer 160. As illustrated, due to the presence of the second cavity 112, the bottom surface of core insulating layer 110 is elevated compared to a bottom base of device 120 on the first carrier member 210

Further, the second circuit layer 140 may be formed on the other surface of the core insulating layer 110. The second circuit layer 140 may be made of a conductive material. For example, the second circuit layer 140 may be made of copper (Cu). However, a material forming the second circuit layer 140 is not limited to copper. That is, any material which is used as a conductive material for a circuit in a circuit board field may be applied to the second circuit layer 140 without being limited. Further, the second circuit layer 140 may be formed by using at least one of known methods for forming a circuit layer such as a tenting method, a modified semi additive process (MASP), and a semi additive process (SAP), and the like.

The second circuit layer 140 may include a second circuit pattern 141 and a first external connection pad 142. The first external connection pad 142 may be electrically connected to the outside. The first external connection pad 142 may be formed with the external connection terminal (not illustrated) such as a solder ball and a solder bump.

According to the embodiment of the present invention, the first circuit layer 160, the second circuit layer 140, and the core insulating layer 110 formed with the through type cavity 113 may be attached to a first carrier member 210. Next, the device 120 may be inserted into a cavity 113. For example, the device 120 may be any of the active device and the passive device. The device 120 may be formed in the cavity 113 by the first carrier member 210 which is formed on one surface (bottom surface) of the cavity 113. Therefore, the one surface of the device 120 may be formed to protrude from the one surface of the core insulating layer 110. According to the embodiment of the present invention, the one surface of the device 120 and the one surface of the first circuit layer 160 may be formed on the same line. However, the above structure is one embodiment of the present invention and therefore the present invention is not limited to the case in which the one surface of the first circuit layer 160 and the one surface of the device 120 are formed on the same line.

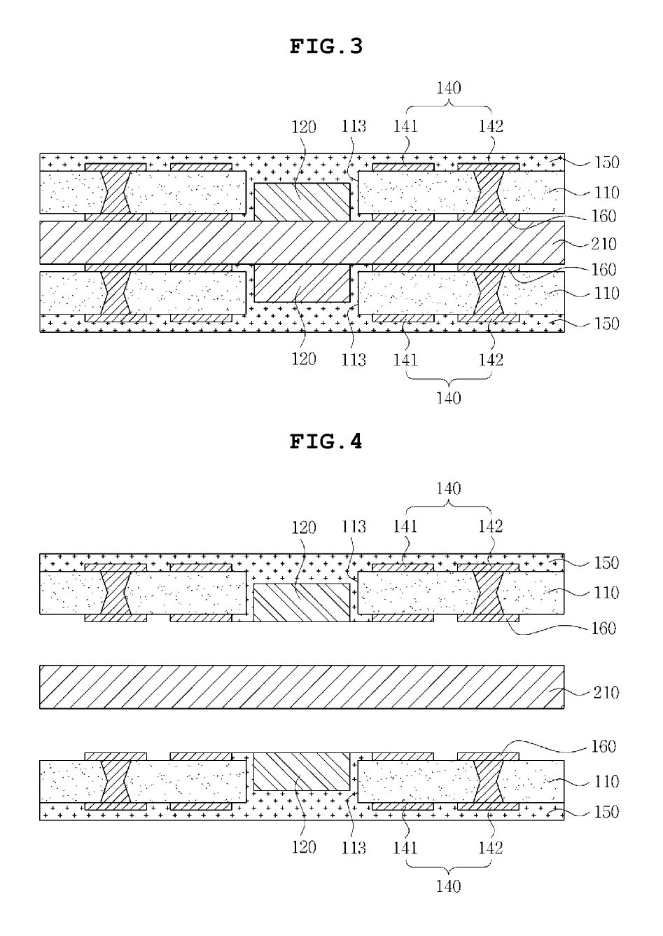

Referring to FIG. 3, the first insulating layer 150 may be formed.

The first insulating layer 150 may be formed on the other surface of the core insulating layer 110. In this case, the first insulating layer 150 may be formed to embed the second circuit layer 140 which is formed on the other surface of the core insulating layer 110. Further, the first insulating layer 150 may be formed to fill the cavity 113 of the core insulating layer 110. In this case, the device 120 may be fixed within the cavity 113 by filling the cavity 113 with the first insulating layer 150.

The first insulating layer 150 according to the embodiment of the present invention may generally be made of an insulating material which is generally used as an interlayer insulating material. That is, the first insulating layer 150 according to the embodiment of the present invention may be selected from the insulating materials known in the circuit board field. For example, the first insulating layer 150 may be made of a solder resist. The solder resist having the lower modulus than that of the core insulating layer 110 has an effect of buffering the external impact. Therefore, the embedded board 100 (FIG. 10) and the device 120 may be protected from the impact due to the bonding process or other processes by filling the cavity 113 with the first insulating layer 150 which is made of the solder resist. However, the first insulating layer 150 is not limited to the solder resist, the first insulating layer 150 may be selectively made from the insulating materials having the lower modulus than that of the core insulating layer 110.

Referring to FIG. 4, the first carrier member 210 may be removed.

According to the first embodiment of the present invention, the embedded board process may be performed by attaching the core insulating layers 110 to both surfaces of the first carrier member 210 but attaching the core insulating layer 110 only to the one surface of the first carrier member 210.

As described above, when the first carrier member 210 is removed, the one surface of the device 120 formed to protrude from the core insulating layer 10 may also be exposed to the outside. Further, a portion of the first insulating layer 150 enclosing the device 120 within the cavity 113 may be exposed to the outside.

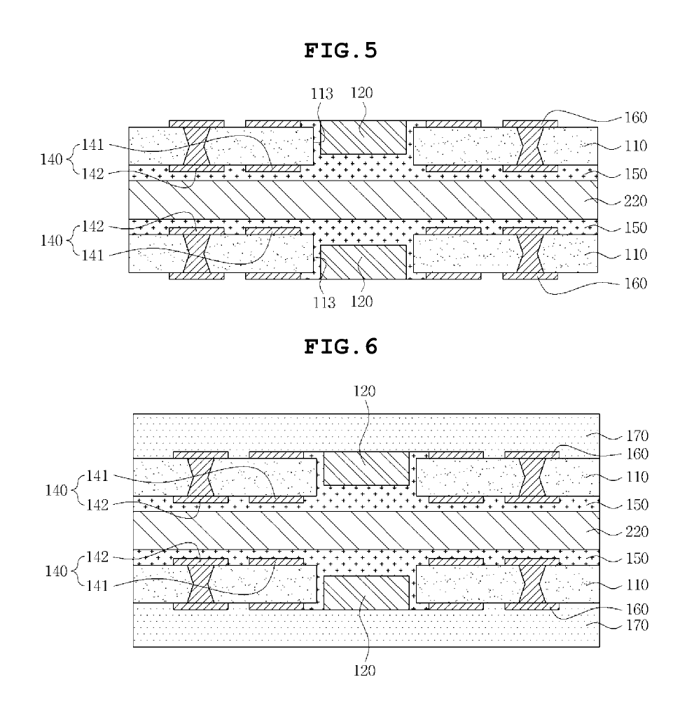

Referring to FIG. 5, the core insulating layer 110 on which the device 120 is disposed may be attached to the second carrier member 220.

The core insulating layer 110 from which the first carrier member 210 (FIG. 4) is removed may be attached to the second carrier member 220. Herein, the second carrier member 220 may serve to support the substrate during the process in the circuit board field and then may be removed later.

The core insulating layer 110 may be attached to one surface or both surfaces of the second carrier member 220. In this case, the first insulating layer 150 of the core insulating layer 110 may be attached to contact the second carrier member 220.

Referring to FIG. 6, the build-up insulating layer 170 may be formed.

The build-up insulating layer 170 may be formed on one surface of the core insulating layer 110 and thus may be formed to embed the first circuit layer 160. Further, the build-up insulating layer 170 may be formed on the device 120 protruding from the core insulating layer 110 and the first insulating layer 150.

The build-up insulating layer 170 may be generally made of the composite polymer resin used as the interlayer insulating material. For example, the build-up insulating layer 170 may be made of an epoxy based resin, such as prepreg, ajinomoto build-up film (ABF), FR-4, and bismaleimide triazine (BT). However, according to the embodiment of the present invention, a material forming the build-up insulating layer 170 is not limited thereto. The build-up insulating layer 170 according to the embodiment of the present invention may be selected from the insulating materials known in the circuit board field.

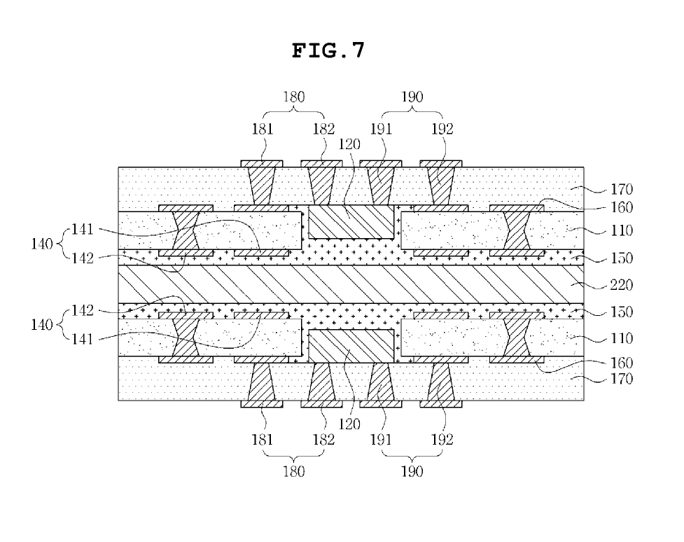

Referring to FIG. 7, the build-up circuit layer 180 and the via 190 may be formed.

The build-up circuit layer 180 may be formed on one surface of the build-up insulating layer 170. The build-up circuit layer 180 may be made of a conductive material. For example, the build-up circuit layer 180 may be made of copper (Cu). However, a material forming the build-up circuit layer 180 is not limited to copper. That is, any material which is used as a conductive material for a circuit in a circuit board field may be applied to the build-up circuit layer 180 without being limited.

The via 190 may be formed inside the build-up insulating layer 170. The via 190 may include a first via 191 and a second via 192. For example, the first via 191 may electrically connect the build-up circuit 180 to the device 120. The second via 192 may electrically connect the build-up circuit layer 180 to the first circuit layer 160. According to the embodiment of the present invention, since the device 120 is formed to protrude from the core insulating layer 110, the first via 191 and the second via 192 may be formed to have a similar height. That is, a height difference between the first via 191 and the second via 192 may be equal to or less than a height difference between one surface of the first circuit layer 160 and one surface of the second cavity 112. For example, when the one surface of the first circuit layer 160 and the one surface of the device 120 are disposed on the same line, the first via 191 and the second via 192 may be formed to have the same height. As the height of the first via 191 is equal or similar to that of the second via 192, the plating defect which occurs due to the difference in a size at the time of forming the via may be prevented. Here, when the via having different sizes is formed, the plating defect may include the case in which any one of the vias is excessively plated or the case in which the via hole is not completely filled. As such, the plating defect may be prevented and thus the reliability of the signal transfer may be improved.

As the method of forming the build-up circuit layer 180 and the via 190 according to the embodiment of the present invention, any one of the methods for forming a circuit layer and a via in the circuit substrate field may be applied.

Further, the embodiment of the present invention describes the example in which the build-up insulating layer 170, the build-up circuit layer 180, and the via 190 are formed in one layer, but is not limited thereto. That is, the processes of FIGS. 6 and 7 are repeatedly performed, and thus the multi-layered build-up insulating layer 170, the build-up circuit layer 180, and the via 190 may be formed.

Further, the build-up circuit layer 180 formed at the outermost layer may include a build-up circuit pattern 181 and a second external connection pad 182. The second external connection pad 182 may be electrically connected to the outside.

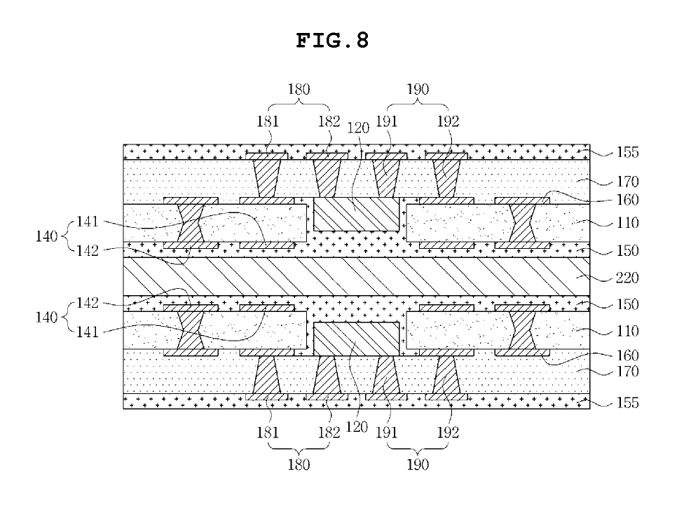

Referring to FIG. 8, the second insulating layer 155 may be formed.

The second insulating layer 155 is formed on the build-up insulating layer 170 and thus may be formed to embed the build-up circuit layer 180. The second insulating layer 155 may be made of an insulating layer which is generally used as an interlayer insulating material. For example, the second insulating layer 155 may be made of the solder resist. However, the material of the second insulating layer 155 is not limited to the solder resist. That is, the second insulating layer 155 according to the embodiment of the present invention may be selected from the insulating materials known in the circuit board field.

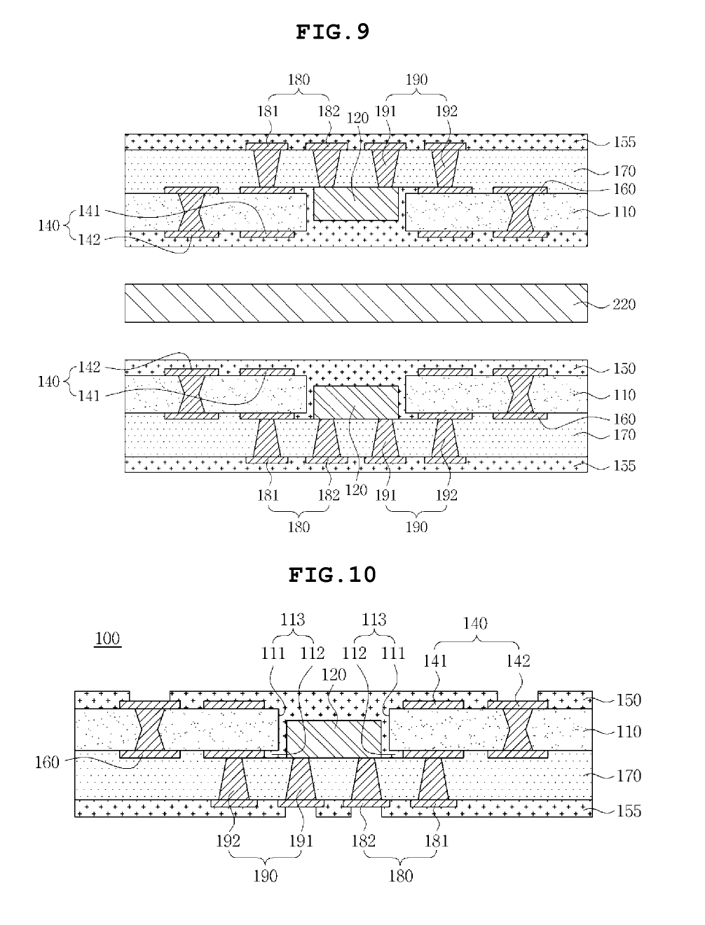

Referring to FIG. 9, the second carrier member 220 may be removed.

Referring to FIG. 10, the first insulting layer 150 and the second insulating layer 155 may be patterned.

According to the embodiment of the present invention, when the second circuit layer 140 includes the first external connection pad 142, the first insulating layer 150 may be patterned to expose the first external connection pad 142.

Further, when the build-up circuit layer 180 includes the second external connection pad 182, the second insulating layer 155 may be patterned to expose the second external connection pad 182.

The embodiment of the present invention describes that the patterning of the first insulating layer 150 and the second insulating layer 155 are simultaneously performed in the final stage, but is not limited thereto. For example, the first insulating layer 150 and the second insulating layer 155 may be individually patterned in different processes. After the first insulating layer 150 is formed, the patterning order of the first insulating layer 150 may be freely defined by the selection of those skilled in the art. Further, in the case of the second insulating layer 155, the second insulating layer 155 may be omitted by the selection of those skilled in the art.

With reference to FIGS. 2 to 10 as described above, the embedded board 100 of FIG. 1 may be formed.

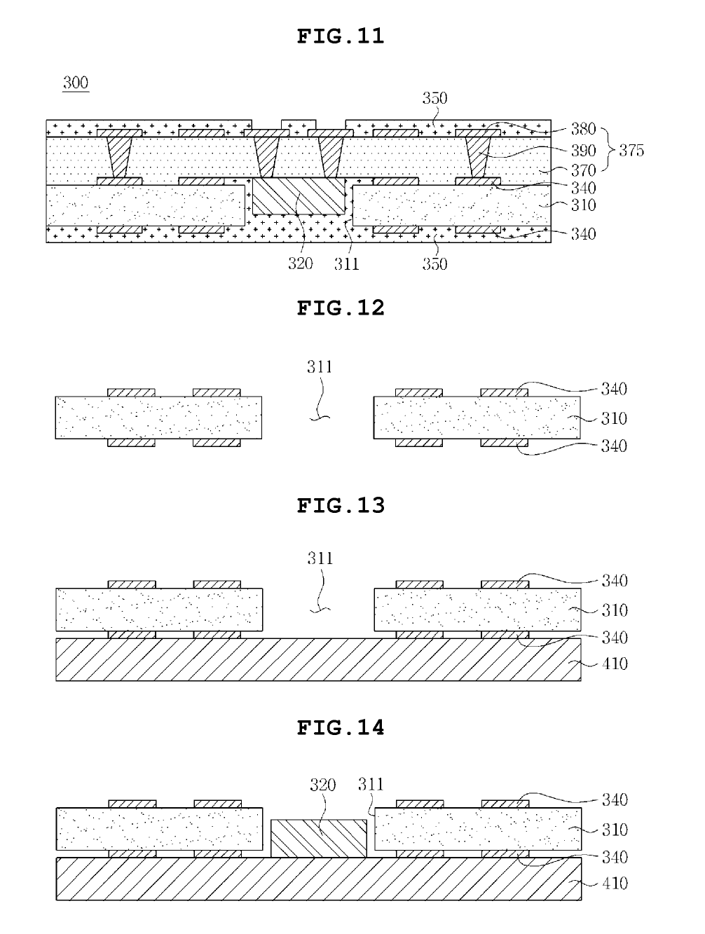

FIG. 11 is an exemplified view illustrating a printed circuit board according to an embodiment of the present invention.

Referring to FIG. 11, a printed circuit board 300 may include a core insulating layer 310, a circuit layer 340, a build-up layer 375, a device 320, and a solder resist 350.

According to the embodiment of the present invention, the core insulating layer 310 may be generally made of a composite polymer resin used as an interlayer insulating material. For example, the core insulating layer 310 may be made of prepreg or an ajinomoto build-up film (ABF). In addition, the core insulating layer 310 may use an epoxy based resin, such as FR-4 and bismaleimide triazine (BT), but is not particularly limited thereto. Further, the core insulating layer 310 may be formed using the copper clad laminate (CCL). The embodiment of the present invention illustrates that the core insulating layer 310 is configured of a single insulating layer, but is not limited thereto. That is, an inside of the core insulating layer 310 may be formed with an insulating layer and a circuit layer which are configured of at least one layer.

According to the embodiment of the present invention, the core insulating layer 310 may include a cavity 311. The cavity 311 may be formed to penetrate through the core insulating layer 110.

According to the embodiment of the present invention, the circuit layers 340 may be formed on both surfaces of the core insulating layer 310. However, the present invention is not limited to the structure in which the circuit layers 340 are formed on both surfaces of the core insulating layer 310. For example, the circuit layer 340 may be formed only on one of both surfaces of the core insulating layer 310. Alternatively, the circuit layer 340 may be omitted. The circuit layer 340 according to the embodiment of the present invention may be made of a conductive material. For example, the circuit layer 340 may be made of copper. However, the material of the circuit layer 340 is not limited thereto and any one of the conductive materials for circuit used in the circuit board field may be applied.

According to the embodiment of the present invention, a build-up layer 375 may be formed on one surface of the core insulating layer 310. According to the embodiment of the present invention, the build-up layer 375 may include a build-up insulating layer 370, a build-up circuit layer 380, and a via 390.

The build-up insulating layer 370 may be formed on one surface of the core insulating layer 310. The build-up insulating layer 370 may be generally made of the composite polymer resin used as the interlayer insulating material. For example, the build-up insulating layer 370 may be made of an epoxy based resin, such as prepreg, ajinomoto build-up film (ABF), FR-4, and bismaleimide triazine (BT). However, according to the embodiment of the present invention, a material forming the build-up insulating layer 370 is not limited thereto. The build-up insulating layer 370 according to the embodiment of the present invention may be selected from the insulating materials known in the circuit board field.

The build-up circuit layer 380 may be formed on the build-up insulating layer 370. The build-up circuit layer 380 may be made of a conductive material. For example, the build-up circuit layer 380 may be made of copper (Cu). However, a material forming the build-up circuit layer 380 is not limited to copper. That is, any material which is used as a conductive material for a circuit in a circuit board field may be applied to the build-up circuit layer 380 without being limited.

The via 390 may be formed inside the build-up insulating layer 370. The via 390 penetrates through the build-up insulating layer 370 and may electrically connect the build-up circuit layer 380 to the device 320. Further, the via 390 may electrically connect the circuit layer 340 to the build-up circuit layer 380.

The embodiment of the present invention describes the example in which the build-up insulating layer 370 and the build-up circuit layer 380 are formed in one layer, but is not limited thereto. For example, the build-up layer 375 may be formed to include the build-up insulating layer 370 and the build-up circuit layer 380 which are formed in multi layers. As described above, when the build-up layer 375 is formed to include a multilayered build-up circuit layer 380, the via 390 may be formed to electrically connect the build-up circuit layers 380 of each layer with each other.

According to the embodiment of the present invention, the device 320 may be disposed in the cavity 311 of the core insulating layer 310. The device 320 according to the embodiment of the present invention may be any of the active device and the passive device. According to the embodiment of the present invention, the device 320 disposed in the cavity 311 may be formed to protrude from the core insulating layer 310. That is, the one surface of the device 320 may be formed to protrude from the one surface of the core insulating layer 310.

The solder resist 350 according to the embodiment of the present invention may be formed on the other surface of the core insulating layer 310. Further, the solder resist 350 may be filling at least a portion of the cavity 311. According to the embodiment of the present invention, the solder resist 350 may be formed around the device 320 disposed in the cavity 311. Therefore, the solder resist 350 formed in the cavity 311 may be formed to protrude from the one surface of the core insulating layer 310. Further, the solder resist 350 formed (filled) in the cavity 311 and the solder resist 350 formed on the other surface of the core insulating layer 310 may be continuously formed. The so formed solder resist 350 may have a thickness thicker than that of the core insulating layer 310. That is, a sum of the thickness of the solder resist 350 filled in the cavity 311 and the thickness of the solder resist 350 formed on the other surface of the core insulating layer 310 may be larger than the thickness of the core insulating layer 310.

The solder resist 350 having the lower modulus than that of the core insulating layer 310 has an effect of buffering the external impact. Therefore, the solder resist 350 is formed in the cavity 311 in which the device 320 is disposed and on the other surface of the core insulating layer 310, thereby protecting the printed circuit board 300 and the device 320 from the external impact. Here, the external impact may be an impact which occurs while the processes for forming the printed circuit board 300 such as the bonding process are performed.

Further, according to the embodiment of the present invention, the solder resist 350 may be formed on one surface of the build-up layer 375. The solder resist 350 formed on the one surface of the build-up layer 375 may be formed to protect the build-up circuit layer 380 from the external impact and the soldering and to prevent the build-up circuit layer 380 from being oxidized from the external impact and the soldering. In this case, the solder resist 350 may be patterned to expose a portion of the build-up circuit layer 380 to the outside. Herein, the build-up circuit layer 380 exposed to the outside may be an area electrically connected to the outside.

FIGS. 12 through 18 are exemplified views illustrating a method of manufacturing a printed circuit board according to the embodiment of the present invention.

Referring to FIG. 12, the core insulating layer 310 may be prepared.

According to the embodiment of the present invention, the core insulating layer 310 may be generally made of a composite polymer resin used as an interlayer insulating material. For example, the core insulating layer 310 may be made of prepreg or an ajinomoto build-up film (ABF). In addition, the core insulating layer 310 may use an epoxy based resin, such as FR-4 and bismaleimide triazine (BT), but is not particularly limited thereto. Further, the core insulating layer 310 may be formed using the copper clad laminate (CCL). The embodiment of the present invention illustrates that the core insulating layer 310 is configured of a single insulating layer, but is not limited thereto. That is, an inside of the core insulating layer 310 may be formed with an insulating layer and a circuit layer which are configured of at least one layer.

According to the embodiment of the present invention, the cavity 311 may be formed in the core insulating layer 310. The cavity 311 may be formed to penetrate through the core insulating layer 110. The cavity 311 may be formed by machining the core insulating layer 110 using laser drill or CNC drill.

Further, the circuit layers 340 may be formed on both surfaces of the core insulating layer 310. However, the present invention is not limited to the structure in which the circuit layers 340 are formed on both surfaces of the core insulating layer 310. For example, the circuit layer 340 may be formed only on one of the core insulating layer 310. Alternatively, the circuit layer 340 may be omitted. The circuit layer 340 according to the embodiment of the present invention may be made of a conductive material. For example, the circuit layer 340 may be made of copper. However, the material of the circuit layer 340 is not limited thereto and any one of the conductive materials for circuit used in the circuit board field may be applied. Further, the circuit layer 340 may be formed by using at least one of known methods for forming a circuit layer such as the tenting method, the modified semi additive process (MASP), and the semi additive process (SAP), and the like.

Referring to FIG. 13, a carrier member 410 may be attached on one surface of the core insulating layer 310.

According to the embodiment of the present invention, the carrier member 410 may contact the circuit layer 340 formed on one surface of the core insulating layer 310. However, when the circuit layer 340 is omitted, the carrier member 410 may contact the one surface of the core insulating layer 310.

Referring to FIG. 14, the device 320 may be disposed.

According to the embodiment of the present invention, the device 320 may be disposed in the cavity 311 of the core insulating layer 310. In this case, the device 320 may be formed to protrude from the one surface of the core insulating layer 310 by the circuit layer 340 formed on the one surface of the core insulating layer 310.

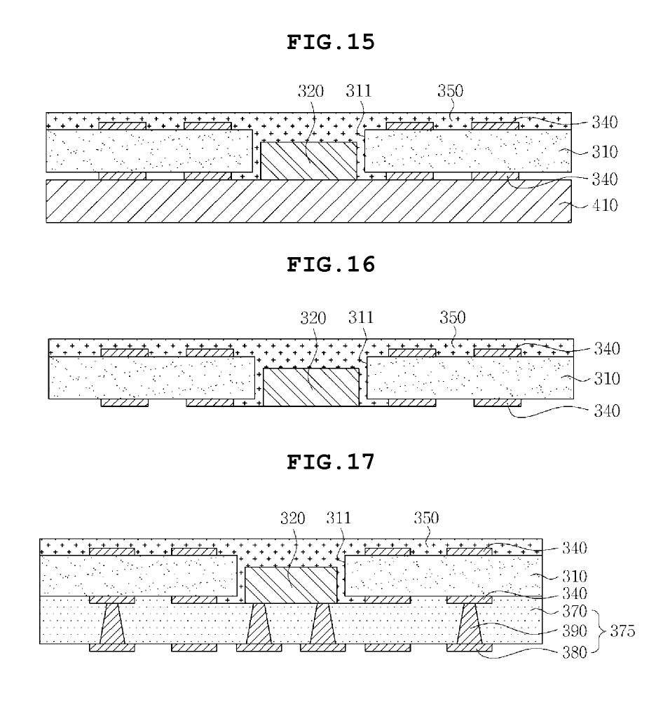

Referring to FIG. 15, the solder resist 350 may be formed.

According to the embodiment of the present invention, the solder resist 350 may be formed on the other surface of the core insulating layer 310. Further, the solder resist 350 may be formed to be filling at least a portion of the cavity 311 of the core insulating layer 310.

For example, the solder resist 350 is laminated on the other surface of the core insulating layer 310 in the film form and then heated, and thus may be formed on the other surface of the core insulating layer 310 and in the cavity 311. Alternatively, the solder resist 350 is printed in a liquid form and may be formed on the other surface of the core insulating layer 310 and in the cavity 311.

The formed solder resist 350 as described above may be formed around the device 320 disposed in the cavity 311. Therefore, the solder resist 350 formed in the cavity 311 may be formed to protrude from the one surface of the core insulating layer 310. Further, the solder resist 350 formed (filled) in the cavity 311 and the solder resist 350 formed on the other surface of the core insulating layer 310 may be continuously formed. The so formed solder resist 350 may have a thickness thicker than that of the core insulating layer 310. That is, a sum of the thickness of the solder resist 350 filled in the cavity 311 and the thickness of the solder resist 350 formed on the other surface of the core insulating layer 310 may be larger than the thickness of the core insulating layer 310.

The embodiment of the present invention describes the example in which the solder resist 350 is filled in the overall inside of the cavity 311, but is not limited thereto.

Referring to FIG. 16, the carrier member 410 (FIG. 15) may be removed.

According to the embodiment of the present invention, a portion of the device 320 may be exposed by removing the carrier member 410 (FIG. 15). Here, an exposed portion of the device 320 may be a portion protruding from the one surface of the core insulating layer 310. Further, a portion of the solder resist 350 enclosing the device 320 may also be exposed. Here, the exposed portion of the solder resist 350 may be a portion protruding from the one surface of the core insulating layer 310.

Referring to FIG. 17, the build-up layer 375 may be formed.

According to the embodiment of the present invention, the build-up layer 375 may be formed on one surface of the core insulating layer 310. According to the embodiment of the present invention, the build-up layer 375 may include the build-up insulating layer 370, the build-up circuit layer 380, and the via 390.

The build-up insulating layer 370 may be formed on one surface of the core insulating layer 310. The build-up insulating layer 370 may be generally made of the composite polymer resin used as the interlayer insulating material. For example, the build-up insulating layer 370 may be made of an epoxy based resin, such as prepreg, ajinomoto build-up film (ABF), FR-4, and bismaleimide triazine (BT). However, according to the embodiment of the present invention, a material forming the build-up insulating layer 370 is not limited thereto. The build-up insulating layer 370 according to the embodiment of the present invention may be selected from the insulating materials known in the circuit board field.

The build-up circuit layer 380 may be formed on the build-up insulating layer 370. The build-up circuit layer 380 may be made of a conductive material. For example, the build-up circuit layer 380 may be made of copper (Cu). However, a material forming the build-up circuit layer 380 is not limited to copper. That is, any material which is used as a conductive material for a circuit in a circuit board field may be applied to the build-up circuit layer 380 without being limited.

The via 390 may be formed inside the build-up insulating layer 370. The via 390 penetrates through the build-up insulating layer 370 and may electrically connect the build-up circuit layer 380 to the device 320. Further, the via 390 may electrically connect the circuit layer 340 to the build-up circuit layer 380.

For example, the build-up insulating layer 370 may be formed on one surface of the core insulating layer 310. Next, the via 390 penetrating through the build-up layer 375 and the build-up circuit layer 380 may be sequentially formed or simultaneously formed. The via 390 and the build-up circuit layer 380 may be formed by using at least one of the known methods such as the tenting method, the modified semi additive process (MASP), and the semi additive process (SAP), and the like.

The embodiment of the present invention describes the example in which the build-up insulating layer 370 and the build-up circuit layer 380 are formed in one layer, but is not limited thereto. For example, the build-up layer 375 may include the build-up insulating layer 370 and the build-up circuit layer 380 which are formed in multi layers. As described above, when the build-up layer 375 is formed to include a multilayered build-up circuit layer 380, the via 390 may be formed to electrically connect the build-up circuit layers 380 of each layer with each other.

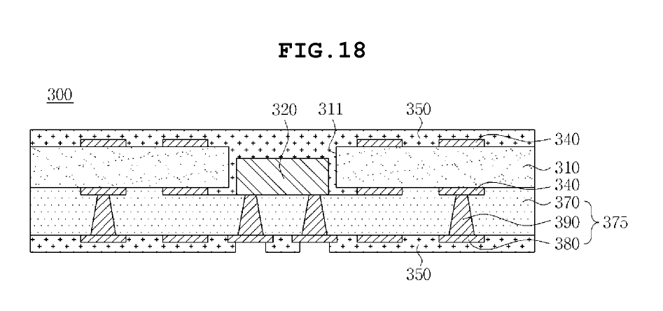

Referring to FIG. 18, the solder resist 350 may be formed on the build-up layer 375.

According to the embodiment of the present invention, the solder resist 350 formed on the one surface of the build-up layer 375 may be formed to protect the build-up circuit layer 380 from the external impact and the soldering and to prevent the build-up circuit layer 380 from being oxidized from the external impact and the soldering. In this case, the solder resist 350 may be patterned to expose a portion of the build-up circuit layer 380 to the outside. Herein, the build-up circuit layer 380 exposed to the outside may be an area electrically connected to the outside.

With reference to FIGS. 12 through 18 as described above, the printed circuit board 300 of FIG. 11 may be formed.

According to the embedded board, the printed circuit board, and the method of manufacturing the same in accordance with the embodiments of the present invention, it is possible to buffer the external impact by using the insulating material having a low modulus.

Further, according to the embedded board, the printed circuit board, and the method of manufacturing the same in accordance with the embodiments of the present invention, it is possible to improve the reliability of the signal transfer by overcoming the plating defect of the via.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be defined by the accompanying claims and their equivalents.

What is claimed is:

1. An embedded board, comprising:
a core insulating layer formed with a first cavity;
a first circuit layer formed on one surface of the core insulating layer;
a build-up insulating layer formed on one surface of the core insulating layer and formed with a second cavity extending from the first cavity;
a device disposed in the first cavity and the second cavity and formed to protrude from one surface of the core insulating layer;
a first insulating layer formed on the other surface of the core insulating layer and filling the first cavity and the second cavity; and
a via formed in the build-up insulating layer.

2. The embedded board as set forth in claim 1, wherein the first insulating layer and the build-up insulating layer are made of different respective materials.

3. The embedded board as set forth in claim 1, wherein the first insulating layer is made of a solder resist.

4. The embedded board as set forth in claim 1, further comprising:
a second circuit layer formed on the other surface of the core insulating layer.

5. The embedded board as set forth in claim 4, wherein the second circuit layer includes a first external connection pad and the first insulating layer is formed with an opening through which the first external connection pad is exposed.

6. The embedded board as set forth in claim 1, further comprising:
a build-up circuit layer formed on the build-up insulating layer.

7. The embedded board as set forth in claim 6, wherein the via includes a first via which electrically connects the build-up circuit layer to the device and a second via which electrically connects the first circuit layer to the build-up circuit layer.

8. The embedded board as set forth in claim 7, wherein the first via and the second via have the same height.

9. The embedded board as set forth in claim 6, further comprising:
a second insulating layer formed on the build-up circuit layer.

10. The embedded board as set forth in claim 9, wherein the build-up circuit layer includes a second external connection pad and the second insulating layer is formed with an opening through which the second external connection pad is exposed.

11. The embedded board as set forth in claim 6, wherein the build-up insulating layer and the build-up circuit layer are each formed in multi layers.

12. A method of manufacturing an embedded board, comprising:
preparing a core insulating layer, which has a first cavity though the core insulating layer, and a first circuit layer including a second cavity extending from the first cavity;
attaching the core insulating layer so as to contact the first circuit layer to one surface or both surfaces of the first carrier member;
disposing a device in the first cavity and the second cavity;
forming a first insulating layer on the other surface of the core insulating layer such that the first insulating layer fills the first cavity and the second cavity;
removing the first carrier member; and
forming a build-up insulating layer on one surface of the core insulating layer.

13. The method as set forth in claim 12, wherein in the preparing of the core insulating layer, a second circuit layer is further formed on the other surface of the core insulating layer.

14. The method as set forth in claim 12, wherein the second circuit layer includes a first external connection pad, and
in the forming of the first insulating layer, the first insulating layer is formed with an opening through the first external connection pad is exposed.

15. The method as set forth in claim 12, further comprising:
after the forming of the build-up insulating layer, forming a build-up circuit layer and a via on the build-up insulating layer.

16. The method as set forth in claim 15, further comprising:
after the forming of the build-up circuit layer and the via, forming a second insulating layer on the build-up circuit layer.

17. The method as set forth in claim 16, wherein the build-up circuit layer includes a second external connection pad, and
in the forming of the second insulating layer, the second insulating layer is formed with an opening through the second external connection pad is exposed.

18. The method as set forth in claim 12, wherein the first insulating layer and the build-up insulating layer are made of different materials.

19. The method as set forth in claim 12, wherein the first insulating layer is made of a solder resist.

20. The method as set forth in claim 15, wherein in the forming of the build-up circuit layer and the via, a first via which electrically connects the build-up circuit layer to the device and a second via which electrically connects the first circuit layer to the build-up circuit layer are formed.

21. The method as set forth in claim 20, wherein the first via and the second via have the same height.

22. The method as set forth in claim 15, wherein the build-up insulating layer and the build-up circuit layer are each formed in multi layers.

23. The method as set forth in claim 12, further comprising:
after the removing of the first carrier member, attaching a core insulating layer on which the device is disposed so as to contact the first insulating layer to one surface or both surfaces of the second carrier member.

24. The method as set forth in claim 23, further comprising:
after the forming of the build-up insulating layer, removing the second carrier member.

25. A printed circuit board, comprising:
a core insulating layer formed with a cavity;
a build-up layer formed on one surface of the core insulating layer;
a solder resist formed on the other surface of the core insulating layer and filling at least a portion of the cavity; and
a device disposed in the cavity.

26. The printed circuit board as set forth in claim 25, wherein the solder resist filled in the cavity is formed around the device.

27. The printed circuit board as set forth in claim 25, wherein the solder resist filled in the cavity and the solder resist formed on the other surface of the core insulating layer are continuously formed.

28. The printed circuit board as set forth in claim 25, wherein a sum of a thickness of the solder resist filled in the cavity and a thickness of the solder resist formed on the other surface of the core insulating layer is larger than that of the core insulating layer.

29. The printed circuit board as set forth in claim 25, wherein the solder resist filled in the cavity is formed to protrude from one surface of the core insulating layer.

30. A method of manufacturing a printed circuit board, comprising:
attaching a carrier member to one surface of a core insulating layer formed with a cavity;
disposing a device in the cavity;
forming a solder resist on the other surface of the core insulating layer and in the cavity;
removing the carrier member; and
forming a build-up insulating layer on one surface of the core insulating layer.

31. The method as set forth in claim 30, further comprising:
after the forming of the build-up insulating layer, forming a build-up circuit layer and a via on the build-up insulating layer.

32. The method as set forth in claim 31, further comprising:
after the forming of the build-up circuit layer and the via, forming a solder resist layer on one surface of the build-up circuit layer.

33. A printed circuit board, comprising:
a core insulating layer formed with a cavity;
a build-up layer formed on a first surface of the core insulating layer and having a recess on a side of the build-up layer facing the first surface of the core insulating layer;
a device, partly located in the cavity, protruding out of the cavity and into the recess.

34. The printed circuit board of claim 33, the printed circuit board further comprising:
a build-up circuit layer formed on a surface of the build-up layer that is opposite to the side of the build-up layer facing the first surface of core insulating layer;
a first circuit layer formed on the first surface of the core insulating layer;
a first via passing through the build-up layer, interposed between a portion of the build-up circuit layer and the device, and electrically connecting the device and the build-up circuit layer; and
a second via passing through the build-up layer, interposed between a portion of the build-up circuit layer and a portion of first circuit layer, electrically connecting the first circuit layer and the build-up circuit layer, and having a height that is the same as that of the first via.

35. The printed circuit board as set forth in claim 33, further comprising:
a further insulating layer formed on a second surface of the core insulating layer opposite to the first surface of the core insulating layer, made of a material with a lower modulus than that of the core insulating layer, and filling at least a portion of the cavity and at least a portion of the recess.

36. A method of manufacturing the printed circuit board of claim 33, comprising:
arranging the device and the core insulating layer formed with the cavity on a carrier, such that the device is inside the cavity with a bottom base on the carrier and the first surface of the core insulating layer is elevated to a position above the bottom base of the device;
forming a further insulating layer by filling a space around the device, such that the further insulating layer is partially in the cavity and protruding out of the cavity; and
removing the carrier and then forming the build-up layer on the first surface of the core insulating layer.
